(19) United States
(12) Patent Application Publication
(10) Pub. No.: US 2010/0270672 A1
(43) Pub. Date: Oct. 28, 2010

(54) Semiconductor device

(75) Inventor: Seiichi Shiraki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/654,903

(22) Filed: Jan. 7, 2010

(30) Foreign Application Priority Data
Jan. 8, 2009 (JP) 2009-002665

(51) Int. Cl. H01L 23/498; H01L 21/3205

(52) U.S. Cl. 257/737; 438/674; 257/E23.069; 257/E21.294

(57) ABSTRACT

A semiconductor device includes a conductive section formed on a semiconductor chip; and a bump electrode formed directly or indirectly on the conductive section. The conductive section includes a slit section having a thickness thinner than another portion of the conductive section. The bump electrode has a recessed section corresponds to the slit section above the slit section.

### INCORPORATION BY REFERENCE

This patent application claims a priority on convention based on Japanese Patent Application No. 2009-002665. This disclosure thereof is incorporated herein by reference.

### BACKGROUND OF THE INVENTION

1. Field of the Invention

The present invention relates to a semiconductor device and a method of manufacturing same, and more specifically to a semiconductor device having a bump electrode structure and a method of manufacturing the same.

2. Description of Related Art

In recent years, a bonding pad section of a semiconductor device has become narrower and smaller. On the other hand, the number of bonding pads has increased. With these changes, displacement of a probe card needle has more frequently occurred when a chip test is performed on the surface of a bump electrode. When the displacement of the probe card needle occurs, the needle is sometimes contact with a pattern other than the bump electrode in some cases. As a result, damage to the surface of the semiconductor device occurs, leading to a product failure.

FIG. 1 is a sectional view of a pad structure of a conventional semiconductor device. The surface of an Al layer bonding pad 1 on the side of a bump electrode 7 is flat, and thus the surface of the bump electrode 7 is also almost flat. Small steps are actually present on the surface of the bump electrode 7 in left and right ends of the Al layer bonding pad 1. However, a distance between the steps is approximately several tens of micrometers, and thus the surface of the bump electrode 7 is shaped gently and is substantially flat. As a result of this, when the displacement of a probe card needle occurs, the needle slides off the bump electrode 7 and is thus displaced therefrom, and makes contact with a portion of a pattern other than the bump electrode 7, so that the pattern is damaged.

In connection with the above description, Japanese Patent Application Publication (JP 2003-347351A: first conventional example) discloses the invention related to a semiconductor device. The semiconductor device of the first conventional example includes a semiconductor substrate, a wiring layer, a projected layer, and a conductive layer. Here, the semiconductor substrate has a semiconductor element section. The wiring layer is formed on a main surface of the semiconductor substrate. On a predetermined pad region, there is provided at least one projected layer selectively formed on the wiring layer. The conductive layer covers an uneven surface of an exposed surface of the projected layer and an exposed surface of the wiring layer in the pad region.

### SUMMARY OF THE INVENTION

In an aspect of the present invention, a semiconductor device includes a conductive section formed on a semiconductor chip; and a bump electrode formed directly or indirectly on the conductive section. The conductive section includes a slit section having a thickness thinner than another portion of the conductive section. The bump electrode has a recessed section corresponds to the slit section above the slit section.

In another aspect of the present invention, a method of manufacturing a semiconductor device, includes forming on a semiconductor chip, a conductive section which comprises a slit section having a thickness thinner than another part of the conductive section; and forming a bump electrode on the conductive section such that a recessed section is formed in correspondence to the slit section above the slit section.

An uneven portion is formed on the surface of a bump electrode 7. A recessed portion on the surface of the bump electrode 7 can prevent displacement of a probe card needle. In the present invention, a slit section 2 is previously provided in an Al layer bonding pad 1, and an HDP (High Density Plasma) interlayer insulating film 4 and a SiON film 5 or a SiN film 5 are formed thereon, and a bump electrode 7 is further formed thereon. At this point, an uneven portion is formed at each layer above the slit section 2.

### BRIEF DESCRIPTION OF THE DRAWINGS

FIG. 1 is a sectional view of a pad structure of a semiconductor device according to a conventional technique;

FIG. 2 is a plan view of an Al layer bonding pad according to the conventional technique;

FIG. 3 is a sectional view of the pad structure after an HDP interlayer insulating film is formed and an SiON film or an SiN film is formed on the HDP interlayer oxide film according to the conventional technique;

FIG. 4 is a sectional view of the pad structure after a cover opening 6 is formed according to the conventional technique;

FIG. 5 is a plan view of an Al layer bonding pad 1 of a semiconductor device according to a first embodiment of the present invention;

FIG. 6 is a sectional view of the semiconductor device according to the first embodiment of the present invention after an HDP interlayer insulating layer and a SiON film or a SiN film is formed;

FIG. 7 is a sectional view of the semiconductor device according to the first embodiment of the present invention after a cover opening is formed;

FIG. 8 is a sectional view of the semiconductor device according to the first embodiment of the present invention after a bump electrode is formed;

FIG. 9 is a plan view of an example of the Al layer bonding pad of the semiconductor device according to a second embodiment of the present invention;

FIG. 10 is a plan view of another example of the Al layer bonding pad of the semiconductor device according to the second embodiment of the present invention;

FIG. 11 is a sectional view of the semiconductor device according to the second embodiment of the present invention;

FIG. 12 is a plan view of the Al layer bonding pad according to a third embodiment of the present invention;

FIG. 13 is a sectional view of the semiconductor device according to the third embodiment of the present invention; and

FIG. 14 is a plan view of a plurality of Al layer bonding pads according to a fourth embodiment of the present invention.

### DESCRIPTION OF PREFERRED EMBODIMENTS

Hereinafter, a semiconductor device according to the present invention will be described with reference to the attached drawings.

Here, before description of the semiconductor according to a first embodiment of the present invention, a conventional method of manufacturing a semiconductor device will be described.

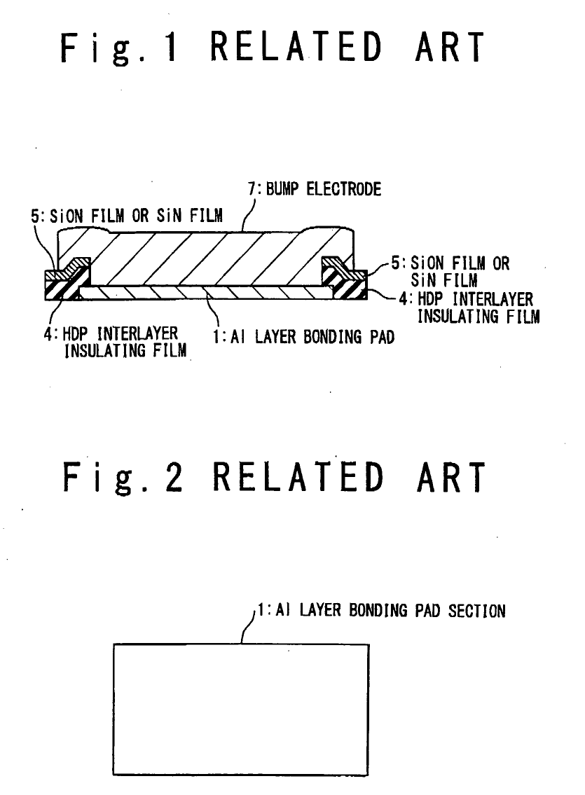

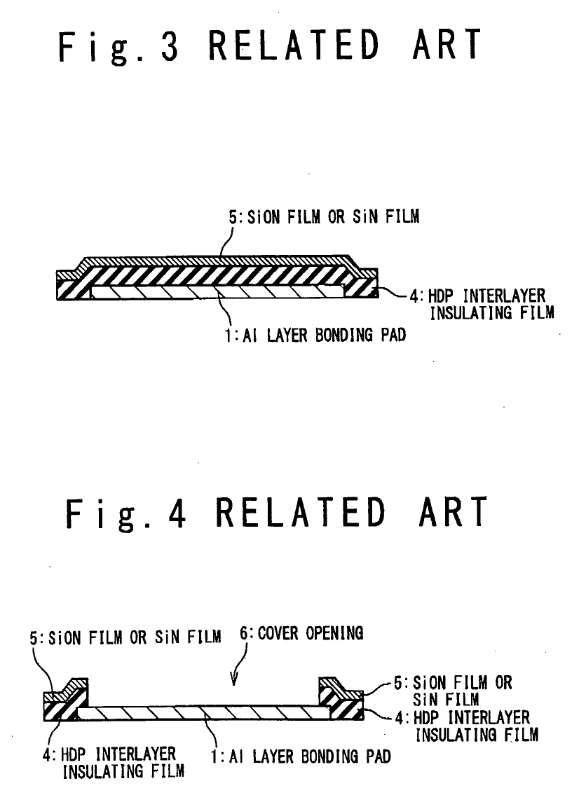

FIG. 2 is a plan view of an Al layer bonding pad 1 in the conventional method. The Al layer bonding pad 1 has a flat surface. FIG. 3 is a sectional view of a pad structure in the conventional method. A high density plasma (HDP) interlayer insulating film 4 is formed on the Al layer bonding pad 1 and a SiON film 5 or a SiN film 5 is formed on the HDP interlayer insulating film 4. FIG. 4 is a sectional view of the pad structure after a cover opening 6 is formed, in the conventional technique. To form the cover opening 6, the HDP interlayer insulating film 4 on the Al layer bonding pad 1 and the SiON film 5 or the SiN film 5 on the HDP interlayer insulating film 4 are etched through a cover PR (Photo Resist) step. After the formation of the cover opening 6, the bump electrode 7 is formed on the Al layer bonding pad 1, thereby providing a result shown in FIG. 1 described above. That is, the surface of the Al layer bonding pad 1 under the bump electrode 7 is flat, and thus the surface of the bump electrode 7 is also almost flat. Small step portions appear on the surface of the bump electrode 7 in both of the left and right ends of the Al layer bonding pad 1. However, a distance between the both step portions is approximately several tens of micrometers, and the surface of the bump electrode 7 is smooth and substantially flat, so that that a probe card needle is easy to slide.

### FIRST EMBODIMENT

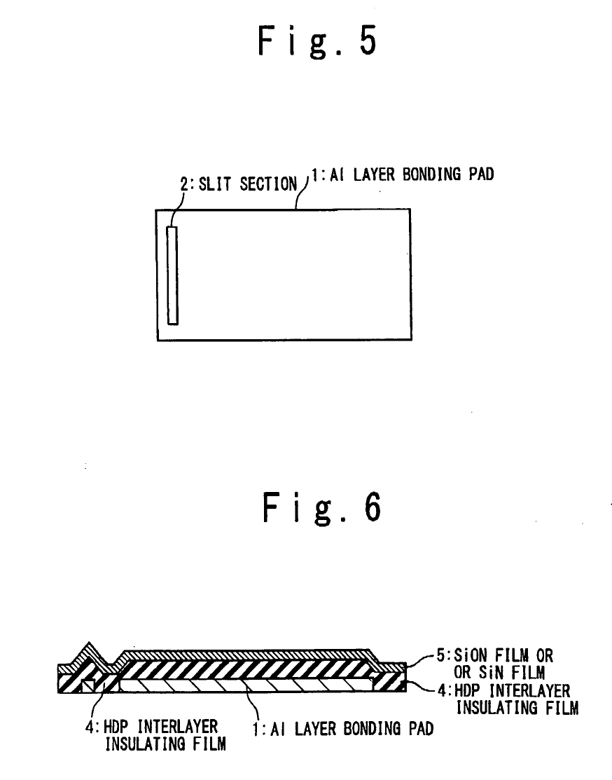

FIG. 5 is a plan view of the Al layer bonding pad 1 of a semiconductor device according to a first embodiment of the present invention. It should be noted that the Al layer bonding pad 1 may be a conductive section formed of a material other than aluminum. The Al layer bonding pad 1 is provided with a slit section 2. It should be noted that, although the slit section 2 does not have to penetrate through the Al layer bonding pad 1, it penetrates through the Al layer bonding pad 1 in a thickness direction thereof in this example. That is, the slit section 2 may be a recessed portion having a sufficient depth from a surface of the Al layer bonding pad 1. Moreover, the shape of the slit section 2 is not limited to a rectangle, and may be freely designed as long as it is located inside an area of the Al layer bonding pad 1. To form the Al layer bonding pad 1, a portion excluding the slit section 2 may be formed from the beginning. Alternatively, after forming an entire area including the slit section 2, the slit section 2 may be removed.

FIG. 6 is a sectional view of the semiconductor device according to the first embodiment of the present invention after the HDP interlayer insulating film 4 is formed on the Al layer bonding pad 1 and then the SiON film 5 or the SiN film 5 is formed on the film 4. An uneven portion is formed on the surfaces of the HDP interlayer insulating film 4 and the SiON film 5 or the SiN film 5 above the slit section 2 in correspondence with the shape of the slit section 2.

It should be noted that the Al layer bonding pad 1 and the HDP interlayer insulating film 4 may not be necessarily in a direct contact with each other. For example, there may be another component between the Al layer bonding pad 1 and the HDP interlayer insulating film 4. Similarly, the HDP interlayer insulating film 4 and the SiON film 5 or the SiN film 5 may not be necessarily in a direct contact with each other. There may be another component between the HDP interlayer insulating film 4 and the SiON film 5 or the SiN film 5.

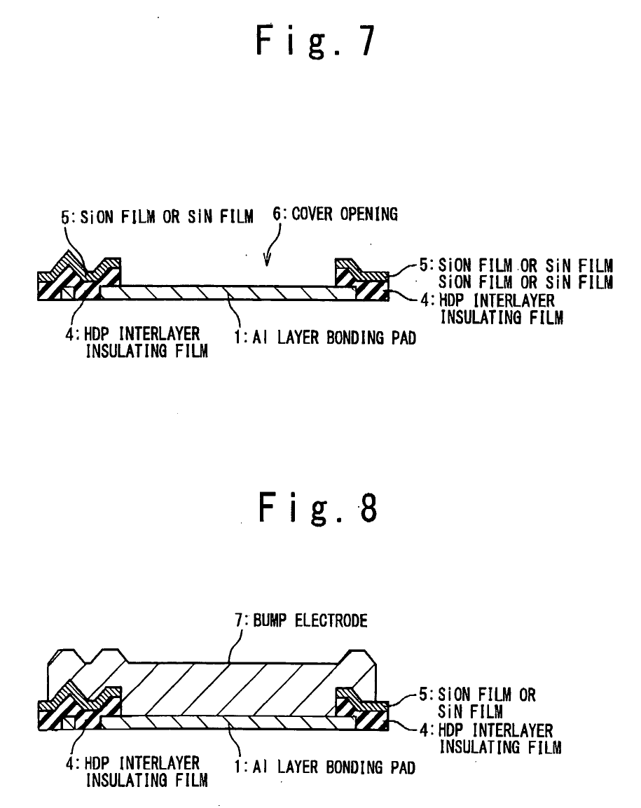

FIG. 7 is a sectional view of the semiconductor device according to the first embodiment of the present invention after the cover opening 6 is formed. To form the cover opening 6, the HDP interlayer insulating film 4 on the Al layer bonding pad 1 and the SiON film 5 or the SiN film 5 on the HDP interlayer insulating film 4 are etched through a cover PR step. A method of forming the cover opening 6 is not limited to etching. The cover opening 6 may be formed by another method. In this case, it is preferable that the cover opening 6 do not extend over the slit section 2.

FIG. 8 is a sectional view of the semiconductor device according to the first embodiment of the present invention after the bump electrode 7 is formed. The surface shape of the bump electrode 7 has an unevenness portion representing the shape of the lower layer. That is, the uneven portion is formed on the surface of the bump electrode 7 above the slit section 2 in correspondence with the shape of the slit section 2. It is preferable that the width of the slit section 2 be approximately several micrometers. It should be noted that the uneven portion on the surface of the bump electrode 7 can be adjusted depending on the width of the slit section 2, the width of the Al layer bonding pad 1, the width of the bump electrode 7, and so on.

The uneven portion formed on the surface of the bump electrode 7 in this manner can serve as a stopper against the probe card needle. As a result of this, even when the needle slides, damage to a pattern other than the bump electrode can be prevented.

### SECOND EMBODIMENT

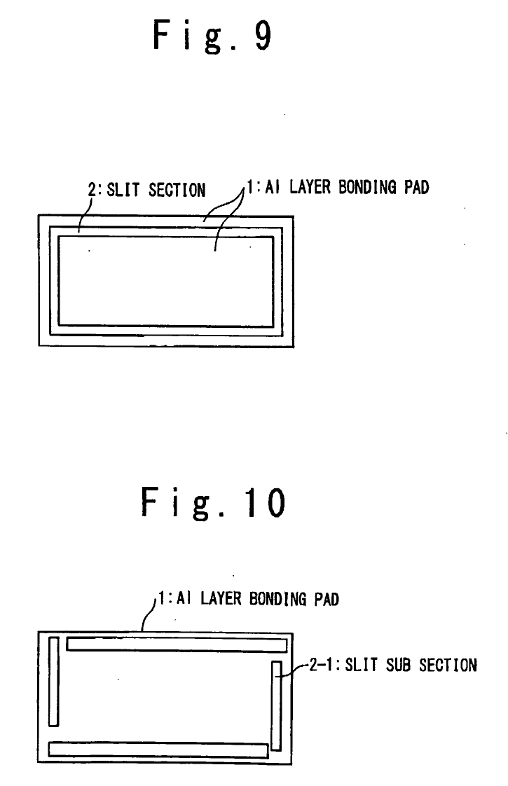

FIG. 9 is a plan view of the Al layer bonding pad 1 of the semiconductor device according to a second embodiment of the present invention. The slit section 2 is provided in the whole of peripheral portion of the Al layer bonding pad 1 to have at least a connection portion between a central portion and a circumferential edge portion. This permits formation of an uneven portion around the bump electrode 7. Therefore, once the probe card needle has been placed down on the central portion of the bump electrode 7, the needle never moves away out of the circumferential edge portion thereof even if the needle slides on the bump electrode 7.

FIG. 10 is a plan view of another example of the Al layer bonding pad 1 of the semiconductor device according to the second embodiment of the present invention. This example is different from FIG. 9 in that the slit section 2 is divided in a plurality of slit sub sections 2-1 to whereby the circumferential edge portion and the central portion of the Al layer bonding pad 1 are unified as one body even when the slit sub sections 2-1 penetrate through the Al layer bonding pad 1. This makes it possible to avoid technical difficulties encountered in a step of forming the Al layer bonding pad 1. It should be noted that if a distance between the two slit sub sections 2-1 is sufficiently smaller than a diameter of the probe card needle, the needle never moves away to the circumferential edge portion of the Al layer bonding pad 1.

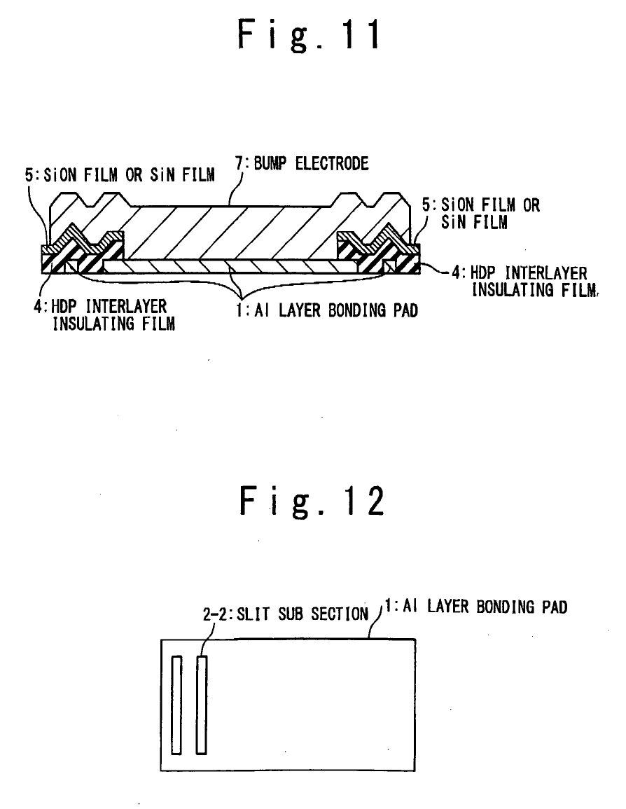

FIG. 11 is a sectional view of the semiconductor device according to the second embodiment of the present invention. The second embodiment is different from the first embodiment shown in FIG. 8 in that there is a recessed portion at both ends of the bump electrode 7 although the recessed portion is actually formed in the circumferential edge portion of the bump electrode 7. Therefore, the circumferential edge portion functions as a stopper in whatever direction the probe card needle slides on the surface of the bump electrode 7.

Other features are the same as those of the first embodiment and thus omitted from description.

### THIRD EMBODIMENT

FIG. 12 is a plan view of the Al layer bonding pad 1 of the semiconductor device according to a third embodiment of the present invention. In this Al layer bonding pad 1, two parallel slit sub sections 2-2 are provided. Using the Al layer bonding pad 1, the HDP interlayer insulating film 4 and the SiON film 5 or the SiN film 5 are formed, as in the first embodiment, and the cover opening 6 is formed, and then the bump electrode 7 is formed.

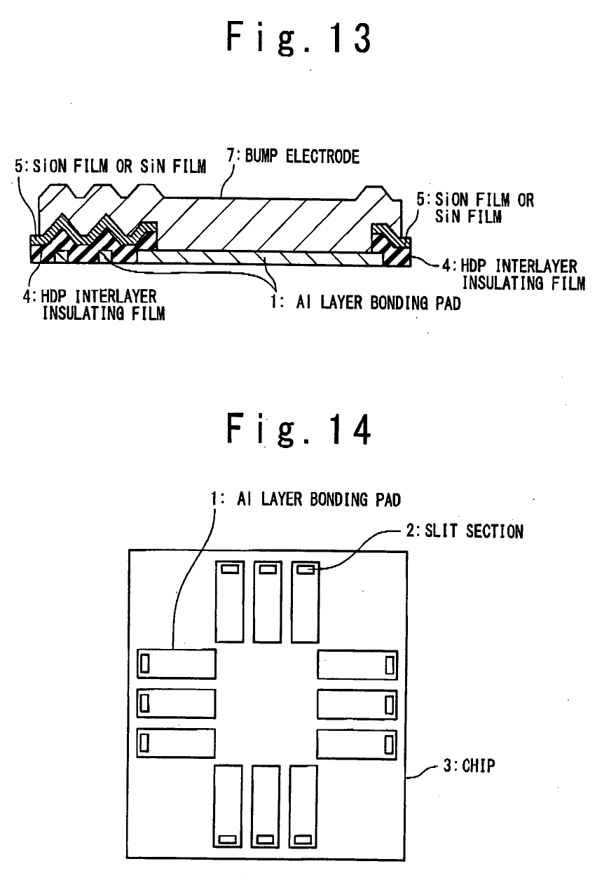

FIG. 13 is a sectional view of the semiconductor device according to the third embodiment of the present invention. The number of uneven portions on the surface of the bump electrode 7 is plural in accordance with the number of slit sub sections 2-2. Since the number of uneven portions is plural, an effect of the stopper against the probe card needle is intensified. That is, even in a case that the probe card needle breaks through a first recessed portion, a second recessed portion serves as the stopper again.

Other features are the same as those of the first embodiment and thus omitted from description.

### FOURTH EMBODIMENT

FIG. 14 is a plan view of a plurality of Al layer bonding pad according to a fourth embodiment of the present invention. Here, a plurality of the Al layer bonding pads 1 each including the slit sections 2 are formed on one semiconductor chip 3. The plurality of Al layer bonding pads 1 are designed such that a plurality of slit sections 2 are arranged at top, bottom, left and right portions located at outer circumference of the semiconductor chip 3. Typically, a probe card needle is probed from the inside to the outside of the semiconductor chip 3. Therefore, according to the present embodiment, even when the needle moves, each of the plurality of slit parts 2 serves as the stopper, further improving an effect provided by the present invention.

A plurality of embodiments of the present invention have been described above, and features of respective embodiments may be freely combined together within a technically consistent range.

What is claimed is:

1. A semiconductor device comprising:
a conductive section formed on said semiconductor chip; and
a bump electrode formed directly or indirectly on said conductive section,
wherein said conductive section comprises:
a slit section having a thickness thinner than another portion of said conductive section,
wherein said bump electrode has a recessed section corresponds to said slit section above said slit section.

2. The semiconductor device according to claim 1, further comprising:
an insulating layer formed between said slit section and said bump electrode.

3. The semiconductor device according to claim 2, wherein said insulating layer comprises:
an HDP interlayer insulating layer formed on said conductive section; and
a SiN film or a SiON film formed on said HDP insulating film.

4. The semiconductor device according to claim 1, wherein said slit section penetrates said conductive section into a direction of the thickness of said conductive section.

5. The semiconductor device according to claim 1, wherein said slit section comprises:
a recessed portion in the direction of the thickness of said conductive section.

6. The semiconductor device according to claim 1, wherein said conductive section comprises a plurality of slit sub sections,
said bump electrode comprises a plurality of said recessed sections corresponding to said plurality of slit sub sections.

7. The semiconductor device according to claim 6, wherein said plurality of slit sub sections are arranged in parallel to each other in said conductive section, and
said plurality of recessed sections are arranged in parallel to each other in said bump electrode.

8. The semiconductor device according to claim 6, wherein said plurality of slit sub sections are distributedly arranged in a circumferential portion of said conductive section, and
said plurality of recessed sections are distributedly arranged in a circumferential portion of said bump electrode.

9. The semiconductor device according to claim 1, further comprising a plurality of said bump electrodes.

10. A method of manufacturing a semiconductor device, comprising:
forming on a semiconductor chip, a conductive section which comprises a slit section having a thickness thinner than another part of said conductive section; and
forming a bump electrode on said conductive section such that a recessed section is formed in correspondence to said slit section above said slit section.

11. The method according to claim 10, further comprising:
forming an insulating layer on said conductive section; and
removing a part of said insulating layer to form a cover opening,
wherein said forming an insulating layer comprises:
forming said insulating layer to leave a recessed portion corresponding to said slit section above said slit section,
wherein said removing comprises:
removing the part of said insulating layer to leave the recess portion of said insulating layer.

12. The method according to claim 11, wherein said forming an insulating layer comprises:
forming an HDP interlayer insulating layer on said conductive section; and
forming a SiON film or a SiN film on said HDP interlayer insulating layer.

13. The method according to claim 10, wherein said forming a conductive section comprises:
forming said conductive section except for said slit section.

14. The method according to claim 10, wherein said forming a conductive section comprises:
forming said conductive section except for said slit section.
forming said conductive section on the whole area of a conductive section forming are; and
removing a part of said conductive section corresponding to said slit section from said conductive section.
